(19) United States
(12) Patent Application Publication
(10) Pub. No.: US 2026/0182201 A1
(43) Pub. Date: Jun. 25, 2026

(54) DISPLAY DEVICE, METHOD OF PROVIDING THE SAME AND ELECTRONIC DEVICE INCLUDING THE SAME

(71) Applicant: Samsung Display Co., LTD., Yongin-si (KR)

(72) Inventors: Do Hyun JUNG, Yongin-si (KR); Hyun KIM, Yongin-si (KR); Il Bae AHN, Yongin-si (KR); Jin Won LEE, Yongin-si (KR); Seul Ki KIM, Yongin-si (KR); Jeong Hwan KIM, Yongin-si (KR); Han Hee YOON, Yongin-si (KR); Seo Hee LEE, Yongin-si (KR)

(21) Appl. No.: 19/401,438

(22) Filed: Nov. 26, 2025

(30) Foreign Application Priority Data
Dec. 24, 2024 (KR) 10-2024-0195821

(51) Int. Cl. H10K 59/80; H10K 59/12; H10K 59/35

(52) U.S. Cl. CPC H10K 59/80515; H10K 59/1201; H10K 59/353; H10K 59/879

(57) ABSTRACT

A display device includes a circuit layer, and light-emitting devices electrically connected to the circuit layer. Each of the light-emitting devices includes pixel electrode, an optical compensation layer, a light-emitting portion and a counter electrode. The pixel electrodes of the light-emitting devices include a first pixel electrode, a second pixel electrode and a third pixel electrode. The optical compensation layers of the light-emitting devices cover each of the first pixel electrode and the second pixel electrode among the first pixel electrode, the second pixel electrode and the third pixel electrode. A thickness of the optical compensation layer covering the first pixel electrode is greater than a thickness of the optical compensation layer covering the second pixel electrode.

This application claims priority to Korean Patent Application No. 10-2024-0195821 filed on Dec. 24, 2024, and all the benefits accruing therefrom under 35 U.S.C. § 119, the entire disclosure of which is incorporated by reference herein.

### BACKGROUND

### (1) Field

Embodiments of the present disclosure relate to a display device, a method of manufacturing (or providing) the same and an electronic device including the same. More particularly, embodiments of the present disclosure relate to a display device including electrodes, a method of manufacturing (or providing) the same, and an electronic device including the same.

### (2) Description of the Related Art

In a display device such as an organic light emitting diode (OLED) display device and a liquid crystal display device (LCD), a display substrate including thin film transistors (TFTs) and various wirings may be provided. A display structure including electrodes and emission layers may be formed (or provided) on (or in) the display substrate.

The emission layers may include different emission patterns implementing different colors. Additionally, different optical and wavelength properties based on the different colors may be implemented by the display structure.

### SUMMARY

According to an embodiment of the present disclosure, there is provided a display device having improved optical properties and image reliability.

According to an embodiment of the present disclosure, there is provided a method of manufacturing a display device having improved optical properties and image reliability.

According to an embodiment of the present disclosure, there is provided an electronic device including a display device with improved optical properties and image reliability.

A display device may include a circuit layer, and light-emitting devices electrically connected to the circuit layer. Each of the light-emitting devices may include pixel electrode, an optical compensation layer, a light-emitting portion and a counter electrode. The pixel electrodes of the light-emitting devices may include a first pixel electrode, a second pixel electrode and a third pixel electrode. The optical compensation layers of the light-emitting devices cover each of the first pixel electrode and the second pixel electrode among the first pixel electrode, the second pixel electrode and the third pixel electrode. A thickness of the optical compensation layer covering the first pixel electrode is greater than a thickness of the optical compensation layer covering the second pixel electrode.

In some embodiments, each of the first pixel electrode, the second pixel electrode and the third pixel electrode of the pixel electrodes may include a transparent conductive oxide pattern. The optical compensation layer may include a transparent conductive oxide material different from a material of the transparent conductive oxide pattern.

In some embodiments, the first pixel electrode, the second pixel electrode and the third pixel electrode may each include indium tin oxide, and the optical compensation layer may include indium zinc oxide.

In some embodiments, each of the first pixel electrode, the second pixel electrode and the third pixel electrode may include a first transparent conductive oxide pattern, a metal pattern and a second transparent conductive oxide pattern sequentially stacked from the circuit layer.

In some embodiments, the optical compensation layer may include a first optical compensation layer covering the first pixel electrode, and a second optical compensation layer covering the second pixel electrode. The thickness of each of the first optical compensation layer and the second optical compensation layer may be greater than a thickness of the transparent conductive oxide pattern included in the first pixel electrode and the second pixel electrode.

In some embodiments, the optical compensation layer may include a first optical compensation layer which covers a top surface and a side surface of the first pixel electrode, and a second optical compensation layer which covers a top surface and a side surface of the second pixel electrode and is separated from the first optical compensation layer.

In some embodiments, the first optical compensation layer and the second optical compensation layer may include a tip portion extending along the circuit layer in a direction toward the second optical compensation layer and the first optical compensation layer, respectively.

In some embodiments, the light-emitting portion may be in contact with the first optical compensation layer and the second optical compensation layer, and may be in contact with the third pixel electrode.

In some embodiments, the light-emitting devices may include a first light-emitting device including the first pixel electrode and the first optical compensation layer, a second light-emitting device including the second pixel electrode and the second optical compensation layer, and a third light-emitting device including the third pixel electrode. The first light-emitting device may emit red light, the second light-emitting device may emit blue light, and the third light-emitting device may emit green light.

In some embodiments, the light-emitting portion may include a first emission layer on the first pixel electrode, a second emission layer on the second pixel electrode, and a third emission layer on the third pixel electrode. The first emission layer, the second emission layer and the third emission layer may be emission layers of different colors.

In some embodiments, the first emission layer may be a red emission layer, the second emission layer may be a blue emission layer, and the third emission layer may be a green emission layer.

In a method of providing a display device, a circuit layer may be provided. A first pixel electrode, a second pixel electrode and a third pixel electrode of light-emitting devices electrically connected to the circuit layer may be provided. An optical compensation layer covering the first pixel electrode, the second pixel electrode and the third pixel electrode may be provided. A first photoresist pattern which overlaps the first pixel electrode and a second photoresist pattern which overlaps the second pixel electrode may be provided on the optical compensation layer. A thickness of the second photoresist pattern may be smaller than a thickness of the first photoresist pattern. Portions of the optical compensation layer may be removed by an etching process using the first photoresist pattern and the second photoresist pattern as etching masks to form a first optical compensation pattern covering the first pixel electrode, and form a second optical compensation pattern covering the second pixel electrode. The thickness of the second photoresist pattern may be reduced to expose a top surface of the second optical compensation pattern from the second photoresist pattern. A thickness of the second optical compensation pattern may be reduced by etching from the top surface, to form a remaining second optical compensation pattern. The first photoresist pattern may be removed after the etching of the second optical compensation layer from the top surface. A light-emitting portion of the light-emitting devices may be provided on the first optical compensation pattern, the remaining second optical compensation pattern, and the third pixel electrode. A counter electrode of the light-emitting devices may be provided on the light-emitting portion.

In some embodiments, in the providing of the first photoresist pattern and the second photoresist pattern, a photoresist layer covering the optical compensation layer may be provided. The photoresist layer may be patterned to remove an entire thickness portion of the photoresist layer which is on the third pixel electrode, and remove a partial thickness portion of the photoresist layer which is on the second pixel electrode.

In some embodiments, the patterning of the photoresist layer may include an exposure process using a mask having a full-tone portion aligned over the third pixel electrode and a half-tone portion aligned over the second pixel electrode.

In some embodiments, in the reducing of the thickness of the second photoresist pattern, a second photoresist residual pattern may be provided on a side surface of the second optical compensation pattern.

In some embodiments, in the reducing of the thickness of the second photoresist pattern, a thickness of the first photoresist pattern may be reduced so that a top surface of the first optical compensation pattern is not exposed.

In some embodiments, each of the first pixel electrode, the second pixel electrode and the third pixel electrode may include indium tin oxide, and the optical compensation layer may include indium zinc oxide.

In some embodiments, in the etching process which removes the portions of the optical compensation layer, an etchant solution having a higher etching selectivity for the optical compensation layer than each of the first pixel electrode, the second pixel electrode, the third pixel electrode may be used.

An electronic device may include a display device, a memory, and a processor executing data included in the memory to control an operation of the display device. The display device may include a circuit layer, and light-emitting devices electrically connected to the circuit layer. Each of the light-emitting devices may include pixel electrode, an optical compensation layer, a light-emitting portion and a counter electrode. The pixel electrodes of the light-emitting devices may include a first pixel electrode, a second pixel electrode and a third pixel electrode. The optical compensation layers of the light-emitting devices cover each of the first pixel electrode and the second pixel electrode among the first pixel electrode, the second pixel electrode and the third pixel electrode. A thickness of the optical compensation layer covering the first pixel electrode is greater than a thickness of the optical compensation layer covering the second pixel electrode.

In some embodiments, the electronic device may include virtual reality or augmented reality glasses, a smartphone, a tablet personal computer, a laptop, a television, a desk monitor, smart glasses, a head-mounted display, a smart watch, or a vehicle display.

In a display device according to embodiments of the invention, optical compensation layers having different thicknesses may be formed on pixel electrodes included in light-emitting devices of different colors. Accordingly, a resonance structure suitable for optical properties of each color may be implemented while preventing mechanical/chemical damages to the pixel electrodes.

### BRIEF DESCRIPTION OF THE DRAWINGS

FIG. 1 is a schematic cross-sectional view illustrating a display device according to embodiments.

FIGS. 2 to 4 are schematic cross-sectional views of light-emitting devices included in a display device according to embodiments.

FIGS. 5 to 13 are schematic cross-sectional views for describing a method of manufacturing (or providing) a display device according to embodiments.

FIG. 14 is an exploded perspective view illustrating an electronic device according to embodiments.

FIG. 15 is a schematic plan view illustrating an arrangement of pixels of a display device included in an electronic device according to embodiments.

FIG. 16 is a block diagram of an electronic device according to an embodiment.

FIG. 17 is a schematic diagram of electronic devices according to various embodiments.

### DETAILED DESCRIPTION

Hereinafter, embodiments of the invention will be described in more detail with reference to the attached drawings. The same reference numerals can be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the invention.

The terms “on”, “connected”, “coupled,” etc., used herein refers to a direct placement/connection/combination, and also refers to a case where another element is interposed two different elements. For example, it will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein..

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

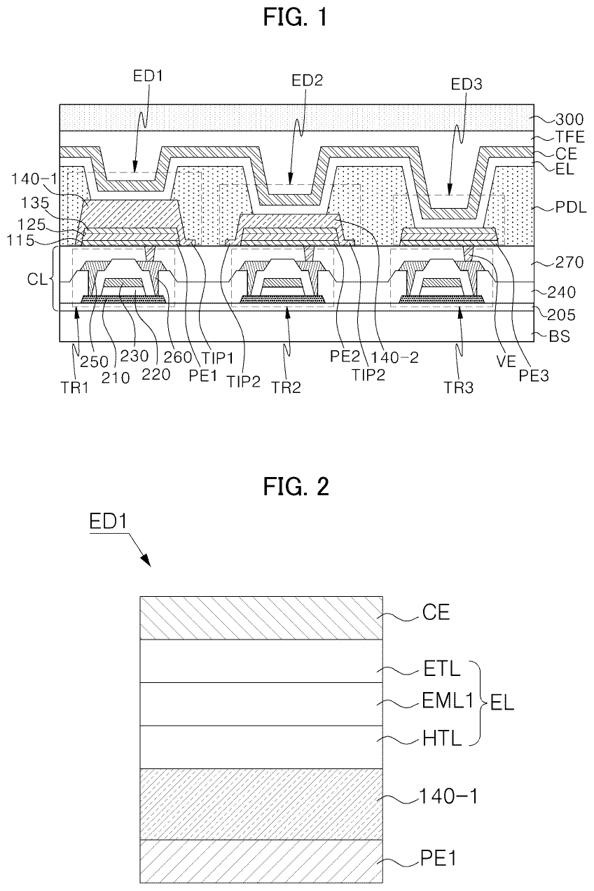

FIG. 1 is a schematic cross-sectional view illustrating a display device DD according to embodiments.

Referring to FIG. 1, a display device DD may include a base substrate BS, a circuit layer CL including a transistor provided in plural including transistors TR1, TR2 and TR3 stacked on the base substrate BS, and a light-emitting device provided in plural including a first light-emitting devices ED1, ED2 and ED3 disposed on the circuit layer CL.

The base substrate BS may serve as a support substrate or a back-plane substrate of an image display device. A glass substrate or a plastic substrate may be used as the base substrate BS.

In some embodiments, the base substrate BS may include a polymer material having transparency and flexibility. In this case, the base substrate BS may be used in a transparent flexible display device. For example, the base substrate BS may include a polymer material such as polyimide, polysiloxane, an epoxy resin, an acrylic resin, polyester, or the like. In an embodiment, the base substrate BS may include polyimide.

The circuit layer CL including the transistors TR1, TR2 and TR3 may be disposed on the base substrate BS. The circuit layer CL may include electrodes, wiring layers, and insulation layers forming (or providing) a thin film transistor array (TFT-Array).

The circuit layer CL may further include a buffer layer 205 formed on a top surface of the base substrate BS. Moisture penetrating through the base substrate BS may be blocked by the buffer layer 205, and diffusion of impurities between the base substrate BS and structures formed on the base substrate BS may be blocked.

The buffer layer 205 may include an inorganic insulating material such as silicon oxide, silicon nitride, or silicon oxynitride. These may be used alone or in a combination thereof. In some embodiments, the buffer layer 205 may have a stacked structure including a silicon oxide layer and a silicon nitride layer.

The buffer layer 205 may be formed by a deposition process such as a chemical vapor deposition (CVD) process, a sputtering process, an atomic layer deposition (ALD) process, or the like, to include the inorganic insulating material.

The transistors TR1, TR2 and TR3 may be disposed on the buffer layer 205. A first transistor TR1, a second transistor TR2 and a third transistor TR3 may be electrically connected to a first light-emitting device ED1, a second light-emitting device ED2 and a third light-emitting device ED3, respectively.

Each of the transistors TR1, TR2 and TR3 may include an active layer 210, a gate insulation layer 220 (or gate insulation pattern), and a gate electrode 230. The circuit layer CL may further include connection electrodes 250 and 260 connected to the active layer 210.

The active layer 210 may be disposed on the buffer layer 205. The active layer may be pattern provided by an active material being patterned by, e.g., a photo-lithography process. The active layer 210 may be repeatedly and/or regularly arranged at each pixel. The active layer 210 may include a silicon compound such as polysilicon. A p-type dopant or an n-type dopant may be doped in a partial region of the active layer 210. The active layer 210 may include a source region and a drain region including the dopant, and a channel region interposed therebetween.

The active layer 210 may include an oxide semiconductor such as indium gallium zinc oxide (IGZO), zinc tin oxide (ZTO), ITZO, ITGZO, or the like.

The gate insulation layer 220 may be formed on the active layer 210, and the gate electrode 230 may be stacked on the gate insulation layer 220. As illustrated in FIG. 1, the gate insulation layer 220 may be formed in a pattern shape partially covering each active layer 210. Alternatively, the gate insulation layer 220 may extend continuously throughout a plurality of pixels or the light-emitting devices ED1, ED2 and ED3, and may be commonly included in the first and third transistors TR1, TR2 and TR3.

The gate electrode 230 may overlap the channel region of the active layer 210, in a vertical direction or a thickness direction of the display device DD.

The gate insulation layer 220 may be formed by the above-mentioned deposition process to include an inorganic insulating material such as silicon oxide, silicon nitride, silicon oxynitride, or the like. In some embodiments, the gate insulation layer 220 having a patterned shape may be formed as illustrated in FIG. 1 by a photo-lithography process in which the gate electrode 230 may be substantially used as an etching mask.

In some embodiments, the gate electrode 230 may be used as an ion implantation mask to form the source region and the drain region in the active layer 210.

An insulating interlayer 240 covering the gate insulation layer 220 and the gate electrode 230 may be formed on the active layer 210. The connection electrodes 250 and 260 which are in contact with or electrically connected to the active layer 210 may be formed on the insulating interlayer 240.

The insulating interlayer 240 may be formed by the above-mentioned deposition process to include an inorganic insulating material such as silicon oxide, silicon nitride, silicon oxynitride, or the like. The insulating interlayer 240 may be formed in a single-layered structure or a multi-layered structure including different materials.

In some embodiments, in the case that the active layer 210 includes an oxide semiconductor, hydrogen may be diffused or moved to defect sites formed in the active layer 210 caused when the patterning process of the gate insulation layer 220. Accordingly, the source region and the drain region may be formed at one side portion and the other side portion of the active layer 210, respectively.

The connection electrodes 250 and 260 as transistor electrodes may penetrate the insulating interlayer 240 and may be connected (e.g., electrically) to the active layer 210. If the gate insulation layer 220 is continuously formed commonly in a plurality of pixel regions, the connection electrodes 250 and 260 may also penetrate the gate insulation layer 220.

In some embodiments, the connection electrodes 250 and 260 may include a source electrode 250 connected to or in contact with the source region of the active layer 210 and a drain electrode 260 connected to or in contact with the drain region of the active layer 210.

Contact holes may be formed by partially etching the insulating interlayer 240. For example, the contact holes exposing the source region and the drain region through the insulating interlayer 240, may be formed. A metal (material) layer filling the contact holes may be formed on the insulating interlayer 240 and extend into the contact holes, and then the metal layer may be partially etched to form the source electrode 250 and the drain electrode 260.

The gate electrode 230 and the connection electrodes 250 and 260 may include a metal such as Ag, Mg, Al, W, Cu, Ni, Cr, Mo, Ti, Pt, Ta, Nd, Sc, or the like, an alloy thereof, or a nitride thereof. The gate electrode 230 and the connection electrodes 250 and 260 may be formed by the deposition process and the photo-lithography process as mentioned above.

A planarization layer 270 covering the connection electrodes 250 and 260 may be formed on the insulating interlayer 240. The planarization layer 270 in which a via hole is defined may accommodate a via electrode VE electrically connecting pixel electrodes PE1, PE2 and PE3, to the drain electrode 260 of a respective transistor.

In some embodiments, the planarization layer 270 may include an organic material such as polyimide, an epoxy resin, an acrylic resin, polyester, a siloxane resin, benzocyclobutene (BCB), or the like. The planarization layer 270 may be formed by the above-mentioned deposition process or a coating process such as a spin coating process.

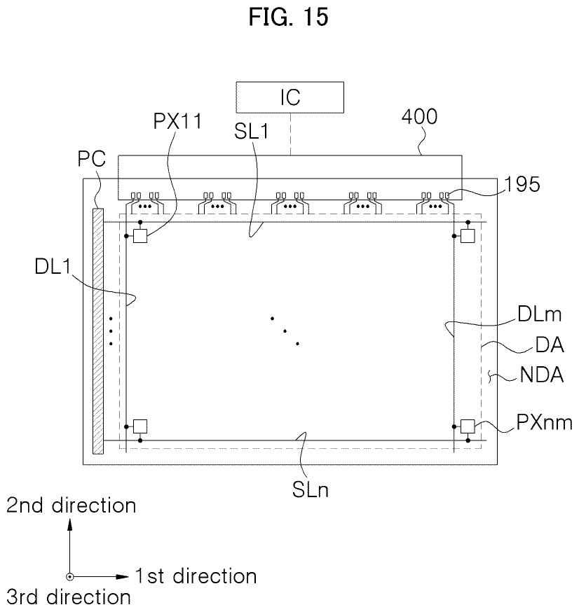

The circuit layer CL may further include scan lines and data lines (see FIG. 15). The scan lines may be connected to the gate electrode 230, and the data lines may be connected to the source electrode 250.

The light-emitting devices ED1, ED2 and ED3 including the pixel electrodes PE1, PE2 and PE3, a light-emitting portion EL as a light-emitting layer, and a counter electrode CE, may be disposed on the circuit layer CL.

The pixel electrodes PE1, PE2 and PE3 may be formed for each pixel to be electrically connected to the transistors TR1, TR2 and TR3, respectively. In an embodiment, the pixel electrodes PE1, PE2 and PE3 may be formed on the planarization layer 270 to be electrically connected to the drain electrode 260.

For example, the planarization layer 270 may be partially etched to form the via hole exposing a top surface of the drain electrode 260 through the planarization layer 270. A conductive (material) layer including a metal or a transparent conductive oxide and filling the via hole may be formed on a top surface of the planarization layer 270, and then the conductive layer may be etched to form the pixel electrodes PE1, PE2 and PE3.

According to embodiments of the present disclosure, the pixel electrodes PE1, PE2 and PE3 may serve as an anode of a light-emitting device. The pixel electrodes PE1, PE2 and PE3 may include the via electrode VE which penetrates the planarization layer 270 to be in contact with or electrically connected to the drain electrode 260.

The pixel electrodes PE1, PE2, and PE3 may include a first pixel electrode PE1, a second pixel electrode PE2 and a third pixel electrode PE3. The first pixel electrode PE1, the second pixel electrode PE2 and the third pixel electrode PE3 may be included as a pixel electrode of the first light-emitting device ED1, the second light-emitting device ED2 and the third light-emitting device ED3, respectively. The first pixel electrode PE1, the second pixel electrode PE2 and the third pixel electrode PE3 may be electrically connected to the first transistor TR1, the second transistor TR2 and the third transistor TR3, respectively.

Each of the first pixel electrode PE1, the second pixel electrode PE2 and the third pixel electrode PE3 may have a multi-layered structure. According to embodiments, each of the first pixel electrode PE1, the second pixel electrode PE2 and the third pixel electrode PE3 may include a sequential stacked structure of a first transparent conductive oxide pattern 115, a metal pattern 125 and a second transparent conductive oxide pattern 135. The first transparent conductive oxide pattern 115, the metal pattern 125 and the second transparent conductive oxide pattern 135 may be sequentially stacked from the top surface of the planarization layer 270, such as to be in order from the top surface.

In some embodiments, the via electrode VE may be formed of a single member substantially integral with the first transparent conductive oxide pattern 115. Here, the via electrode VE and the first transparent conductive oxide pattern 115 may provide a single body. In an embodiment, a barrier metal pattern may be further included under the first transparent conductive oxide pattern 115 of each of the first pixel electrode PE1, the second pixel electrode PE2 and the third pixel electrode PE3. The barrier metal pattern may include a metal such as Ti or Ta for enhancing adhesion to an insulation layer. The barrier metal pattern may be between the first transparent conductive oxide pattern 115 and a respective pixel electrode.

The first transparent conductive oxide pattern 115 and the second transparent conductive oxide pattern 135 may include a transparent conductive oxide such as indium tin oxide (ITO), indium zinc oxide (IZO), zinc oxide (ZnO), indium tin oxide (ITZO), or the like. According to embodiments, each of the first transparent conductive oxide pattern 115 and the second transparent conductive oxide pattern 135 may include ITO.

The metal pattern 125 may include a metal selected from Ag, Mg, Cu, Al, Pt, Pd, Au, Ni, Nd, Ir, Cr, Li, Ca, Mo, Ti, W, In, Sn, and Zn, or an alloy or a compound (e.g., LiF) including at least one therefrom. According to embodiments, the metal pattern 125 may include aluminum (Al).

In some embodiments, the pixel electrodes PE1, PE2 and PE3 may include a triple-layered structure of ITO/Ag/ITO.

An optical compensation layer may be formed on the first pixel electrode PE1 and the second pixel electrode PE2. A first optical compensation layer 140-1 may be formed on the first pixel electrode PE1, and a second optical compensation layer 140-2 may be formed on the second pixel electrode PE2. The patterns of the optical compensation layer may be spaced apart from each other in a direction along the circuit layer CL. The patterns of the optical compensation layer may be in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The first and second optical compensation layers 140-1 and 140-2 may include a transparent conductive oxide. The first and second optical compensation layers 140-1 and 140-2 may include the same transparent conductive oxide. The first and second optical compensation layers 140-1 and 140-2 may include a transparent conductive oxide different from that included in the transparent conductive oxide patterns 115 and 135 of the pixel electrode PE1, PE2 and PE3. That is, the optical compensation layer includes a transparent conductive oxide material different from a material of the transparent conductive oxide pattern.

According to embodiments, the transparent conductive oxide patterns 115 and 135 of the pixel electrodes PE1, PE2, and PE3 may include ITO. The first and second optical compensation layers 140-1 and 140-2 as a third transparent conductive oxide pattern may include IZO. That is, among the pixel electrodes and the optical compensation layer, the first pixel electrode PE1, the second pixel electrode PE2 and the third pixel electrode PE3 each includes ITO, and the optical compensation layer includes IZO.

A thickness of the first optical compensation layer 140-1 may be greater than a thickness of the second optical compensation layer 140-2. A thickness or height of the first optical compensation layer 140-1 from a top surface of the first pixel electrode PE1 (a top surface of the second transparent conductive oxide pattern 135 of the first pixel electrode PE1) may be greater than a thickness or height of the second optical compensation layer 140-2 from a top surface of the second pixel electrode PE2 (a top surface of the second transparent conductive oxide pattern 135 of the second pixel electrode PE2). That is, the optical compensation layer is provided in plural including a first optical compensation layer 140-1 covering the first pixel electrode PE1, and a second optical compensation layer 140-2 covering the second pixel electrode PE2. The thickness of each of the optical compensation layers is greater than a thickness of the transparent conductive oxide pattern included in the first pixel electrode PE1 and the second pixel electrode PE2.

In some embodiments, the optical compensation layer may not be formed on the third pixel electrode PE3.

The first optical compensation layer 140-1 and the second optical compensation layer 140-2 may be in contact with the top surface of the planarization layer 270, and may cover the top surface and side surfaces of the first pixel electrode PE1 and the second pixel electrode PE2, respectively. According to embodiments, the first optical compensation layer 140-1 and the second optical compensation layer 140-2 may entirely cover the first pixel electrode PE1 and the second pixel electrode PE2, respectively, on the planarization layer 270.

The first optical compensation layer 140-1 and the first pixel electrode PE1 may be substantially provided commonly as a first anode of the first light-emitting device ED1. The second optical compensation layer 140-2 and the second pixel electrode PE2 may be substantially provided commonly as a second anode of the second light-emitting device ED2. In the third light-emitting device ED3, the third pixel electrode PE3 may be solely provided as a third anode. Each anode may have a total thickness (or a total height) defined from a reference such as the circuit layer CL.

The first light-emitting device ED1, the second light-emitting device ED2 and the third light-emitting device ED3 may be light-emitting devices which may express different colors from each other. In some embodiments, the first light-emitting device ED1 may be a red (R) light-emitting device, the second light-emitting device ED2 may be a blue (B) light-emitting device, and the third light-emitting device ED3 may be a green (G) light-emitting device.

In embodiments, a display device DD includes a circuit layer CL, and a display layer electrically connected to the circuit layer CL. The display layer includes light-emitting devices which are electrically connected to the circuit layer CL, each of the light-emitting devices including a pixel electrode, a light-emitting layer and a counter electrode. The pixel electrodes of the light-emitting devices include a first pixel electrode PE1, a second pixel electrode PE2 and a third pixel electrode PE3. The light-emitting devices further include an optical compensation layer covering each of the first pixel electrode PE1 and the second pixel electrode PE2 among the first pixel electrode PE1, the second pixel electrode PE2 and the third pixel electrode PE3. A thickness of the optical compensation layer covering the first pixel electrode PE1 is greater than a thickness of the optical compensation layer covering the second pixel electrode PE2.

According to the above-described embodiments, the anodes having different thicknesses or heights may be disposed on the light-emitting devices of different colors. Accordingly, an optimal optical resonance structure may be implemented for each light-emitting device of different colors.

For example, a height of the first anode of the first light-emitting device ED1 corresponding to the red light-emitting device may be increased based on the second anode of the second light-emitting device ED2 corresponding to the blue light-emitting device. A height of the third anode of the third light-emitting device ED3 corresponding to the green light-emitting device may be lowered based on the second anode of the second light-emitting device ED2 corresponding to the blue light-emitting device.

Accordingly, mismatching of the optical length of each light-emitting device may be reduced, and light-emission efficiency of the display device may be enhanced.

In some embodiments, the thickness of the first optical compensation layer 140-1 (the thickness from the top surface of the first pixel electrode PE1) may be greater than a thickness of each of the first transparent conductive oxide pattern 115, the second transparent conductive oxide pattern 135 and the metal pattern 125.

In some embodiments, the thickness of the second optical compensation layer 140-2 (the thickness from the top surface of the second pixel electrode PE2) may be greater than the thickness of each of the first transparent conductive oxide pattern 115 and the second transparent conductive oxide pattern 135, and may be less than the thickness of the metal pattern 125.

For example, the thickness of the first optical compensation layer 140-1 may be in a range from about 900 angstroms (Å) to about 1,500 Å. The thickness of the second optical compensation layer 140-2 may be in a range from about 300 Å to about 600 Å. The thickness of each of the first transparent conductive oxide pattern 115 and the second transparent conductive oxide pattern 135 may be in a range from about 50 Å to about 200 Å, and the thickness of the metal pattern 125 may be in a range from about 600 Å to about 1,000 Å.

In some embodiments, the first optical compensation layer 140-1 may include a first tip portion TIP1, and the second optical compensation layer 140-2 may include a second tip portion TIP2. The tip portion may refer to a portion protruding of the optical compensation layer, from a bottom portion of the optical compensation layer in a horizontal direction along the top surface of the planarization layer 270.

The first tip portion TIP1 of the first optical compensation layer 140-1 may be formed at one side portion of the first optical compensation layer 140-1 in a cross-section of FIG. 1. In some embodiments, the first tip portion TIP1 may be formed only at one side portion of the first optical compensation layer 140-1 and may not be formed at the other side portion in the horizontal direction.

The second tip portion TIP2 of the second optical compensation layer 140-2 may be formed on both side portions (one side portion and the other side portion) of the second optical compensation layer 140-1 in the cross-section of FIG. 1.

Adhesion between the optical compensation layer and the planarization layer 270 may be further enhanced by the tip portion. The optical compensation layer and the planarization layer 270 may overlap each other at a planar area to define a contact area.

A pixel defining layer PDL in which a pixel opening (or a light-emitting opening) is defined may be formed on the planarization layer 270 to expose top surfaces of the pixel electrodes PE1, PE2 and PE3. A pixel region (or a light-emitting area) may be defined by a sidewall of the pixel defining layer PDL. A red light-emitting region (e.g., a first pixel region), a blue light-emitting region (e.g., a second pixel region), and a green light-emitting region (e.g., a third pixel region) may be separated and/or defined by the pixel defining layer PDL, and the first light-emitting device ED1, the second light-emitting device ED2, and the third light-emitting device ED3 may be disposed in the first pixel region, the second pixel region and the third pixel region, respectively. The layers above the planarization layer 270, inclusive of the pixel defining layer PDL through the light-emitting devices (or the encapsulation layer TFE) may be considered a display layer. Here, the display layer is electrically connected to the circuit layer CL.

A light-emitting portion EL may be disposed in each pixel region formed by the pixel defining layer PDL. According to embodiments, the light-emitting portion EL may include an emission layer including an organic light-emitting material. For example, the emission layer may include a fluorescent host and/or a host for a phosphorescent device, and may further include a fluorescent dopant, a phosphorescent dopant, and/or a thermally activated delayed fluorescent (TADF) dopant.

For example, the light-emitting portion EL may be formed by a process such as a vacuum deposition, a spin coating, an inkjet printing, a laser printing, a casting, a laser thermal transfer, or the like.

The counter electrode CE may be disposed on a top surface of the pixel defining layer PDL and the light-emitting portion EL. The counter electrode CE may be a common electrode which may be continuously provided commonly in a plurality of the light-emitting regions or pixels.

The counter electrode CE may serve as an electron injection electrode or a cathode. The counter electrode CE may include a metal, an alloy, an electrically conductive compound, or the like, having a low work function.

For example, the counter electrode CE may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in a combination of two or more therefrom.

The counter electrode CE may be formed as a transmissive electrode, a translucent electrode, or a reflective electrode. The counter electrode CE may have a single-layered structure or a multi-layered structure.

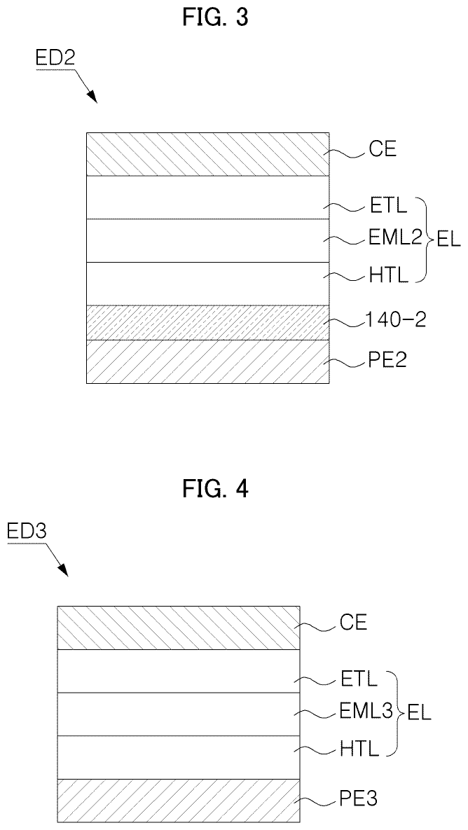

Each of the light-emitting devices ED1, ED2, and ED3 may include the pixel electrodes PE1, PE2 and PE3 on which the optical compensation layer is selectively formed, the light-emitting portion EL and the counter electrode CE. Elements and structures of the light-emitting devices ED1, ED2 and ED3 will be described in more detail with reference to FIGS. 2 to 4.

In some embodiments, an encapsulation layer TFE covering the light-emitting devices ED1, ED2 and ED3 may be disposed on the counter electrode CE. The encapsulation layer TFE may be disposed on the pixel defining layer PDL and the light-emitting devices ED1, ED2 and ED3 to protect the light-emitting devices ED1, ED2 and ED3 from moisture or oxygen.

The encapsulation layer TFE may include an inorganic layer including silicon nitride (SiNx), silicon oxide (SiOx), indium tin oxide, indium zinc oxide or any combination thereof, an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or a combination thereof, or a combination of the inorganic layer and the organic layer.

The encapsulation layer TFE may be formed in a single-layered structure or a multi-layered structure. In some embodiments, the encapsulation layer TFE may have a sequential stacked structure of a first inorganic layer, an organic layer and a second inorganic layer.

The display device DD may further include a functional layer 300 disposed on the encapsulation layer TFE. The functional layer 300 may include a sensor layer such as a touch sensor layer, or an optical layer such as a polarizing layer, a color conversion layer, or a color filter layer.

In some embodiments, the display panel DP may further include a color control portion (not shown) disposed on the light-emitting devices ED1, ED and ED3. The color control portion may include a color filter corresponding to each of the light-emitting devices ED1, ED2 and ED3 or each pixel area.

The color filter may selectively transmit only a light of a specific wavelength band, and may substantially absorb remaining lights. Accordingly, color purity of the display device may be enhanced, and reflection of an external light may be decreased.

The color filter may include, e.g. a first color filter which may transmit a red light having a central wavelength ranging from about 600 nanometers (nm) to about 670 nm, a second color filter which may transmit a blue light having a central wavelength ranging from about 420 nm to about 480 nm, and a third color filter which may transmit a green light having a central wavelength ranging from about 500 nm to about 580 nm.

The first to third color filters may correspond to the first to third light-emitting devices ED1, ED2 and ED3, respectively.

FIGS. 2 to 4 are schematic cross-sectional views of light-emitting devices included in a display device DD according to embodiments.

Referring to FIGS. 2 to 4, the first light-emitting device ED1 may include the first pixel electrode PE1, the first optical compensation layer 140-1, the light-emitting portion EL and the counter electrode CE. The light-emitting portion EL may be disposed between the counter electrode CE and the first optical compensation layer 140-1, and the first optical compensation layer 140-1 may be provided as the anode of the first light-emitting device ED1 together with the first pixel electrode PE1.

The light-emitting portion EL may include a first emission layer EML1, and may further include a hole transport layer HTL formed between the first optical compensation layer 140-1 and the first light-emitting layer EML1, and an electron transport layer ETL formed between the counter electrode CE and the first emission layer EML1.

In some embodiments, the first emission layer EML1 included in the first light-emitting device ED1 may include a red organic light-emitting material, and the first light-emitting device ED1 may be provided as a red light-emitting device.

The second light-emitting device ED2 may include the second pixel electrode PE2, the second optical compensation layer 140-2, the light-emitting portion EL, and the counter electrode CE. The light-emitting portion EL may be disposed between the counter electrode CE and the second optical compensation layer 140-2, and the second optical compensation layer 140-2 may be provided as the anode of the second light-emitting device ED2 together with the second pixel electrode PE2.

The light-emitting portion EL may include a second emission layer EML2, and may further include the hole transport layer HTL formed between the second optical compensation layer 140-2 and the second emission layer EML2, and the electron transport layer ETL formed between the counter electrode CE and the second emission layer EML2.

In some embodiments, the second emission layer EML2 included in the second light-emitting device ED2 may include a blue organic light-emitting material, and the second light-emitting device ED2 may be provided as a blue light-emitting device.

As described with reference to FIG. 1, the thickness of the second optical compensation layer 140-2 may be less than the thickness of the first optical compensation layer 140-1.

The third light-emitting device ED3 may include the third pixel electrode PE3, the counter electrode CE, and the light-emitting portion EL disposed between the third pixel electrode PE3 and the counter electrode CE.

The light-emitting portion EL may include a third emission layer EML3, and may further include the hole transport layer HTL formed between the third pixel electrode PE3 and the third emission layer EML3, and the electron transport layer ETL formed between the counter electrode CE and the third emission layer EML3.

In some embodiments, the third emission layer EML3 included in the third light-emitting device ED3 may include a green organic light-emitting material, and the third light-emitting device ED3 may be provided as a green light-emitting device.

For example, the optical compensation layer including IZO may be omitted from the third light-emitting device ED3. According to embodiments, the light-emitting portion EL may be in direct contact with the third pixel electrode PE3.

For example, the hole transport layer HTL may include a hole transporting material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-l-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material such as an anthracene-based compound, Alq₃ (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, the light-emitting portion EL may further include a hole injection layer (not shown) formed between the pixel electrode and the hole transport layer HTL, or between the optical compensation layer and the hole transport layer HTL. The light-emitting portion EL may further include an electron injection layer (not shown) formed between the counter electrode CE and the electron transport layer ETL.

In some embodiments, one or more of the layers included in the light-emitting portion EL, e.g., the hole transport layer HTL and the electron transport layer ETL may extend continuously and commonly throughout across multiple pixel regions and the top surface of the pixel defining layer PDL. Accordingly, the hole transport layer HTL and the electron transport layer ETL may be formed as common layers of the first to third light-emitting devices ED1, ED2 and ED3.

In some embodiments, the emission layers EML1, EML2 and EML3 may be patterned only in the light-emitting region or the pixel region of each light-emitting device defined by the pixel defining layer PDL. Accordingly, the emission layers EML1, EML2 and EML3 may be separated from each other in the form of islands (e.g., discrete planar shapes) spaced apart from each other in a plurality of pixels.

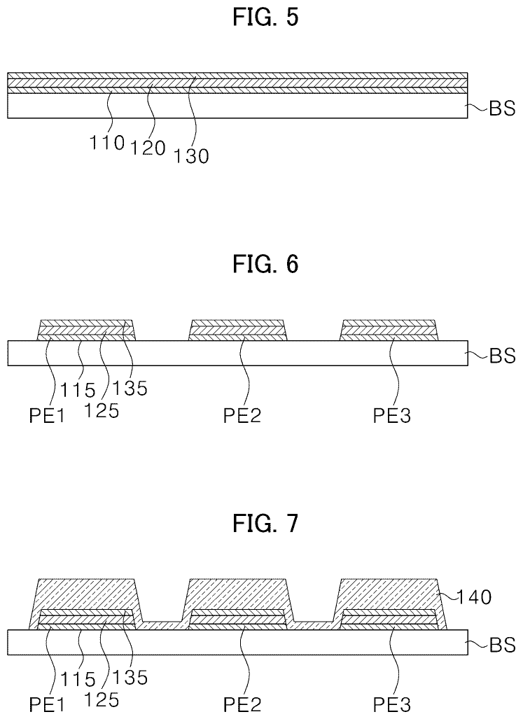

FIGS. 5 to 13 are schematic cross-sectional views illustrating a method of manufacturing (or providing) a display device DD according to embodiments. Detailed descriptions on materials substantially the same as or similar to those described with reference to FIGS. 1 to 4 are omitted. Detailed descriptions on the processes of forming the circuit layer CL, the light-emitting devices ED1, ED2 and ED3, the encapsulation layer TFE, etc., described with reference to FIG. 1 are omitted in FIG. 5.

Referring to FIG. 5, as described with reference to FIG. 1, the circuit layer CL including transistors TR1, TR2, and TR3 may be formed (or provided) on the base substrate BS. In FIG. 5, illustration of the circuit layer CL is omitted for convenience of illustration.

A first transparent conductive oxide layer 110, a metal layer 120 and a second transparent conductive oxide layer 130 may be sequentially formed on the circuit layer CL formed on the base substrate BS. For example, the first transparent conductive oxide layer 110, the metal layer 120 and the second transparent conductive oxide layer 130 may be sequentially formed to fill the via hole on the planarization layer 270 having the via hole formed therein (refer to FIG. 1). The first transparent conductive oxide layer 110, the metal layer 120 and the second transparent conductive oxide layer 130 may be respectively considered a preliminary first transparent conductive oxide (material) layer, a preliminary metal pattern (material) layer and the second transparent conductive oxide (material) layer.

In some embodiments, a barrier metal layer including Ti, Ta, or the like, may be formed in the via hole and on the top surface of the planarization layer 270 in advance.

In some embodiments, the first transparent conductive oxide layer 110 and the second transparent conductive oxide layer 130 may be formed to include a transparent conductive oxide such as ITO. The metal layer 120 may be formed to include Al. The first transparent conductive oxide layer 110, the metal layer 120 and the second transparent conductive oxide layer 130 may be formed by a deposition process such as a sputtering process.

Referring to FIG. 6, the second transparent conductive oxide layer 130, the metal layer 120 and the first transparent conductive oxide layer 110 may be sequentially and partially etched by a photo-lithography process to form the first pixel electrode PE1, the second pixel electrode PE2 and the third pixel electrode PE3, respectively.

Each of the first pixel electrode PE1, the second pixel electrode PE2 and the third pixel electrode PE3 may include patterns of the first transparent conductive oxide pattern 115, the metal pattern 125 and the second transparent conductive oxide pattern 135 sequentially stacked from the top surface of the base substrate BS or the planarization layer 270.

In some embodiments, the first pixel electrode PE1, the second pixel electrode PE2 and the third pixel electrode PE3 may include a triple-layered structure of ITO/Al/ITO. Total thicknesses of the patterns of the first transparent conductive oxide pattern 115, the metal pattern 125 and the second transparent conductive oxide pattern 135 within the first pixel electrode PE1, the second pixel electrode PE2 and the third pixel electrode PE3 may be substantially the same as each other. The preliminary stack of the patterns may be spaced apart from each other along the circuit layer CL, with portions of the circuit layer CL (e.g., the planarization layer 270) exposed therebetween.

Referring to FIG. 7, an optical compensation layer 140 as a preliminary optical compensation (material) layer covering the first to third pixel electrodes PE1, PE2 and PE3 may be formed.

As described above, the optical compensation layer 140 may be formed to include a transparent conductive oxide different from the transparent conductive oxide included in the first transparent conductive oxide pattern 115 and the second transparent conductive oxide pattern 135. In some embodiments, the optical compensation layer 140 may be formed by a deposition process such as a sputtering process to include IZO.

The optical compensation layer 140 may continuously formed along the top surface of the planarization layer 270 and the first to third pixel electrodes PE1, PE2 and PE3, and may commonly cover the first to third pixel electrodes PE1, PE2 and PE3. The preliminary optical compensation (material) layer may have substantially the same thickness overlapping the preliminary stack of patterns at each of the first to third pixel electrodes PE1, PE2 and PE3

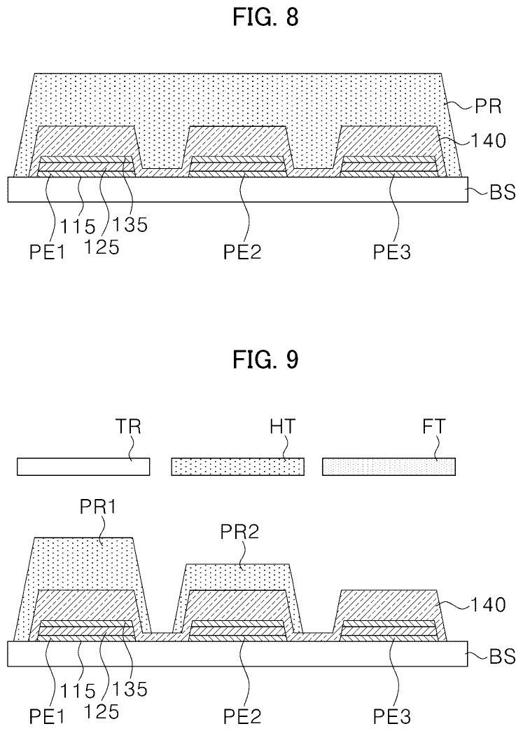

Referring to FIG. 8, a photoresist layer PR covering the optical compensation layer 140 may be formed. The photoresist layer PR may entirely cover the optical compensation layer 140 together with the top surface of the planarization layer 270 which is exposed at locations between the preliminary stack of patterns. Accordingly, the photoresist layer PR may entirely cover the first to third pixel electrodes PE1, PE2 and PE3.

The photoresist layer PR may be formed by coating a composition including a negative-type or positive-type photo-sensitive polymer material.

Referring to FIG. 9, the photoresist layer PR may be patterned by exposure and development processes to form a first photoresist pattern PR1 and a second photoresist pattern PR2.

According to embodiments, the photoresist layer PR may be patterned by a different removal amount (e.g., different thickness portions) for each region using a mask which may include a full-tone portion FT, a half-tone portion HT and a transmissive portion TR.

In some embodiments, when the photoresist layer PR includes the negative-type photo-sensitive polymer, the transmissive portion TR, the half-tone portion HT, and the full-tone portion FT may be disposed or aligned overlapping the first pixel electrode PE1, the second pixel electrode PE2, and the third pixel electrode PE3, respectively.

After arranging the mask, the exposure process may be performed. An amount of light irradiation via the mask by exposure process may be substantially shielded over the third pixel electrode PE3 by the full-tone portion FT, and the amount of light irradiation may be partially supplied over the second pixel electrode PE2. The amount of light irradiation may be substantially completely supplied over the first pixel electrode PE1. Accordingly, the photoresist layer PR may be substantially full-cured at positions correspond to the first pixel electrode PE1 and partially cured over the second pixel electrode PE2.

Thereafter, the photoresist layer PR which is variously cured may be partially removed by the developing process. A thickness portion of the photoresist layer PR on the third pixel electrode PE3 which is substantially uncured by the full-tone portion FT may be substantially removed. Accordingly, a portion of the optical compensation layer 140 covering the third pixel electrode PE3 may be exposed. As illustrated in FIG. 9, a portion of the optical compensation layer 140 extending from a sidewall of the third pixel electrode PE3 and being adjacent to the sidewall of the third pixel electrode PE3 may also be exposed.

A thickness portion of the photoresist layer PR partially cured by the half-tone portion HT may be removed by the development process on the second pixel electrode PE2, and a second photoresist pattern PR2 having a reduced thickness compared to the original thickness of the photoresist layer PR in FIG. 8 may be formed.

A thickness portion of the photoresist layer PR which is initially formed on the first pixel electrode PE1 (refer to FIG. 8) may substantially remain on the first pixel electrode PE1, and a first photoresist pattern PR1 in which the original thickness of the photoresist layer PR is maintained may be formed on a top surface of the first pixel electrode PE1.

A portion of the photoresist layer PR overlapping a portion between the transmissive portion TR and the half-tone portion HT may be removed by the development process. Accordingly, the first photoresist pattern PR1 and the second photoresist pattern PR2 may be formed as independent patterns separated from each other in a direction along the circuit layer CL. As described above, a height or a thickness of the second photoresist pattern PR2 on the top surface of the second pixel electrode PE2 may be less than a height or thickness of the first photoresist pattern PR1 on the top surface of the pixel electrode PE1. Referring to FIG. 9, the optical compensation layer 140 between the first pixel electrode PE1 and the second pixel electrode PE2 may be exposed from the photoresist patterns.

In an embodiment, the providing of the first photoresist pattern PR1 and the second photoresist pattern PR2 may include providing a photoresist layer PR covering the optical compensation layer 140 (FIG. 8), and patterning the photoresist layer PR to remove an entire thickness portion of the photoresist layer PR which is on the third pixel electrode PE3, remove a partial thickness portion of the photoresist layer PR which is on the second pixel electrode PE2, and maintain a thickness of the photoresist layer PR which is on the first pixel electrode PE1 (FIG. 9).

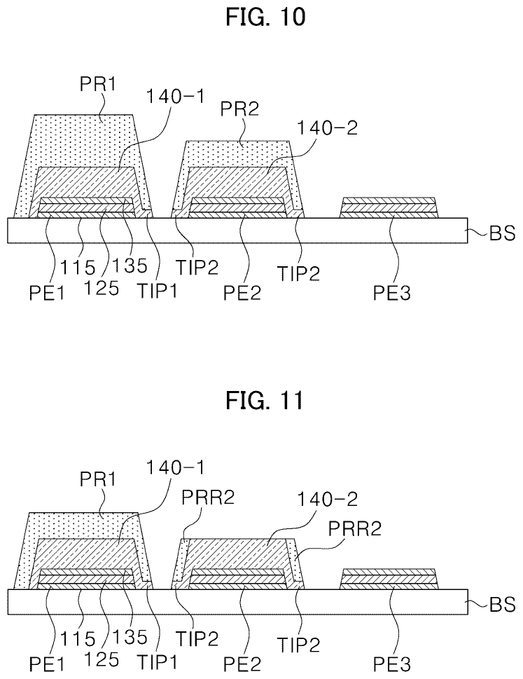

Referring to FIG. 10, the first optical compensation layer 140-1 and the second optical compensation layer 140-2 may be formed by partially etching the optical compensation layer 140. A portion of the optical compensation layer 140 covering the third pixel electrode PE3 may be removed to expose a surface of the third pixel electrode PE3 and the planarization layer 270.

The etching process may include a wet etching process using an etchant having etch selectivity for material forming the transparent conductive oxide included in the optical compensation layer 140 compared to the material forming the transparent conductive oxide patterns 115 and 135 included in the pixel electrodes PE1, PE2 and PE3.

According to embodiments, the wet etching process may be performed using an etchant having an etch selectivity for IZO with respect to ITO. Thus, a portion of the optical compensation layer 140 covering the third pixel electrode PE3 may be selectively removed without causing etching damages to the third pixel electrode PE3.

Further, a portion of the optical compensation layer 140 between the first photoresist pattern PR1 and the second photoresist pattern PR2 may be removed by the etching process. Accordingly, the first optical compensation layer 140-1 covering the first pixel electrode PE1 and the second optical compensation layer 140-2 covering the second pixel electrode PE2 may be physically separated from each other to expose the planarization layer 270.

For example, the optical compensation layer 140 covered by the first photoresist pattern PR1 and the second photoresist pattern PR2 on the top surface of the planarization layer 270, may remain to form a tip portion.

As described with reference to FIG. 1, the first tip portion TIP1 may be formed at one side of the first optical compensation layer 140-1, and the second tip portions TIP2 may be formed at both of opposing sides of the second optical compensation layer 140-2.

In an embodiment, both a respective pixel electrode and a corresponding optical compensation layer may contact the planarization layer 270. The pixel electrode and the optical compensation layer may contact each other. As used herein, elements in contact may form an interface therebetween, such as being in physical contact.

Referring to FIG. 11, the photoresist patterns PR1 and PR2 may be partially removed.

According to embodiments, thickness portions of the photoresist patterns PR1 and PR2 may be gradually removed from top portions thereof by an ashing process or a strip process. The ashing or strip process may be performed until a top surface of the second optical compensation layer 140-2 is exposed from the photoresist patterns. Such ashing or strip process may remove materials in a direction normal (or perpendicular) to the base substrate BS, that is, along a thickness direction of the base substrate BS (or circuit layer CL).

Accordingly, a portion of the second photoresist pattern PR2 formed on the top surface of the second optical compensation layer 140-2 may be substantially removed. A portion of the second photoresist pattern PR2 formed on the side surface of the second optical compensation layer 140-2 may remain. For example, a second photoresist residual pattern PRR2 may remain on the side surface of the second optical compensation layer 140-2. In an embodiment, the reducing of the thickness of the second photoresist pattern PR2 includes providing a second photoresist residual pattern PRR2 on a side surface of the second optical compensation pattern 140-2, the second photoresist residual pattern PRR2 exposing the top surface of the second optical compensation pattern 140-2 from the second photoresist residual pattern.

A thickness of the first photoresist pattern PR1 may be decreased on a top surface of the first optical compensation layer 140-1 by the ashing or strip process while maintaining a state of covering the first optical compensation layer 140-1 at both the upper surface and the side surfaces thereof. In an embodiment, the reducing of the thickness of the second photoresist pattern PR2 further includes reducing a thickness of the first photoresist pattern PR1 together with maintaining the first optical compensation pattern 140-1 overlapped by a thickness portion of the first photoresist pattern PR1.

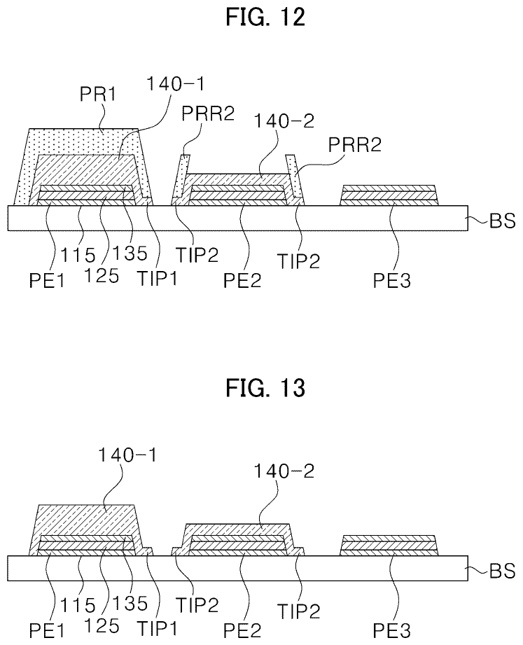

Referring to FIG. 12, an upper thickness portion of the second optical compensation layer 140-2 may be partially etched.

According to embodiments, the upper thickness portion of the second optical compensation layer 140-2 may be partially removed using the etchant solution used in the etching process described with reference to FIG. 10.

Accordingly, a thickness or a height of the second optical compensation layer 140-2 may be reduced from the top surface of the second pixel electrode PE2. An upper thickness portion of the second photoresist residual pattern PRR2 may protrude above the top surface of the second optical compensation layer 140-2 having a reduced thickness as compared to FIG. 11.

Referring to FIG. 13, the first photoresist pattern PR1 and the second photoresist residual pattern PRR2 may be removed by an ashing process or a strip process.

Accordingly, the first pixel electrode PE1 covered by the first optical compensation layer 140-1, the second pixel electrode PE2 covered by the second optical compensation layer 140-2 having a thickness smaller than that of the first optical compensation layer 140-1, and the third pixel electrode PE3 which may not be covered by the optical compensation layer may remain on the circuit layer CL or the planarization layer 270. Referring to FIG. 1, for example, a pixel electrode and the various layers thereon may together define an anode of a respective light-emitting device.

According to the above-described embodiments of the present disclosure, the optical compensation layers having different thicknesses may be respectively formed on the pixel electrodes included in different light-emitting devices using IZO and the etchant solution having an etching selectivity for IZO relatively to ITO may be used in a process of providing the light-emitting devices. Here, the etching process which removes the portions of the optical compensation layer 140 includes using an etchant solution having a higher etching selectivity for the optical compensation layer 140 than each of the first pixel electrode PE1, the second pixel electrode PE2, the third pixel electrode PE3.

Thus, an anode from which the optical compensation layer is omitted, and anodes having the optical compensation layers of different thicknesses may be formed while preventing layer damages (pore formation in a layer, or polymerization of ITO) due to the etching process of the pixel electrodes including the ITO layer in the process of providing the light-emitting devices.

Additionally, the optical compensation layer may be formed using a transparent conductive oxide-based material similar to ITO. Thus, high work function or hole injection properties in the anode may be maintained or enhanced.

Thereafter, as described with reference to FIG. 1, the light-emitting portion EL, the counter electrode CE and the encapsulation layer TFE may be sequentially formed on the first optical compensation layer 140-1, the second optical compensation layer 140-2 and the third pixel electrode PE3. The functional layer 300 may be further formed on the encapsulation layer TFE.

In an embodiment, the method includes providing a circuit layer CL, providing a first pixel electrode PE1, a second pixel electrode PE2 and a third pixel electrode PE3 of light-emitting devices electrically connected to the circuit layer CL (FIGS. 5 and 6), providing an optical compensation layer 140 covering the first pixel electrode PE1, the second pixel electrode PE2 and the third pixel electrode PE3 (FIG. 8), providing on the optical compensation layer 140, a first photoresist pattern PR1 which overlaps the first pixel electrode PE1 and a second photoresist pattern PR2 which overlaps the second pixel electrode PE2, a thickness of the second photoresist pattern PR2 being smaller than a thickness of the first photoresist pattern PR1 (FIG. 9), removing portions of the optical compensation layer 140 by an etching process using the first photoresist pattern PR1 and the second photoresist pattern PR2 as etching masks, to form a first optical compensation pattern 140-1 covering the first pixel electrode PE1, form a second optical compensation pattern 140-2 covering the second pixel electrode PE2, and expose the third pixel electrode PE3 to outside the first optical compensation pattern 140-1 and the second optical compensation pattern 140-2 (FIG. 11), reducing the thickness of the second photoresist pattern PR2 to expose a top surface of the second optical compensation pattern 140-2 to outside the second photoresist pattern PR2 (FIG. 12), reducing a thickness of the second optical compensation layer 140-2, by etching from the top surface, to form a remaining second optical compensation pattern (140-2 in FIG. 12), removing the first photoresist pattern PR1 after the etching of the second optical compensation layer from the top surface (FIG. 13), providing a light-emitting portion of the light-emitting devices on the first optical compensation pattern 140-1, the remaining second optical compensation pattern, and the third pixel electrode PE3, and providing a counter electrode of the light-emitting devices on the light-emitting portion.

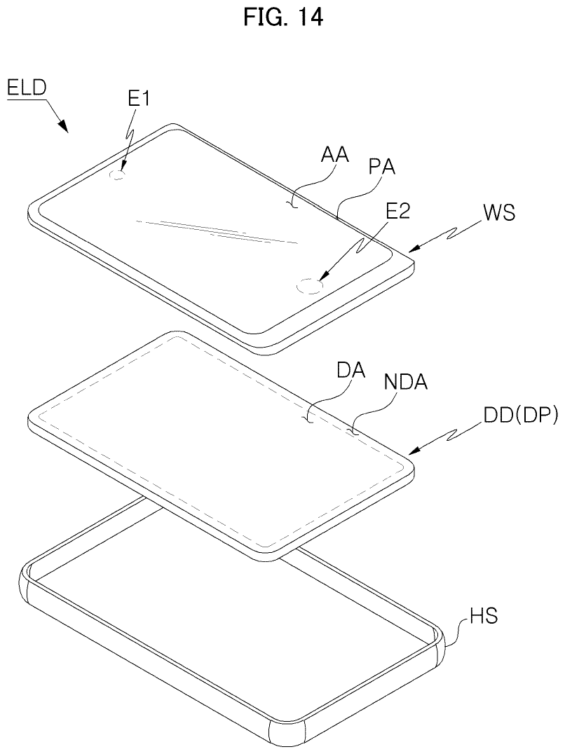

FIG. 14 is an exploded perspective view illustrating an electronic device ELD according to embodiments. FIG. 15 is a schematic plan view illustrating an arrangement of pixels of a display device included in an electronic device according to embodiments.

In FIGS. 14 and 15, a first direction and a second direction may refer to two directions parallel to and perpendicular to a display surface of a window structure WS and/or a display panel DP. For example, the first direction may correspond to an X-direction (a row direction) of a display device DD or the display panel DP, and the second direction may correspond to a Y-direction (column direction) of the display device DD or the display panel DP. The first direction and the second direction may intersect or cross each other to provide a plane. The third direction may be perpendicular to the first direction and the second direction, such as to be normal to the plane. The third direction may be a thickness direction or a height direction of the display device DD, the display panel DP and/or various components or layers thereof.

According to embodiments, the electronic device ELD may be implemented in the form of a mobile phone (smart phone), a tablet, a personal computer (PC), or the like, including the above-described display device.

Referring to FIG. 14, an electronic device ELD may include the window structure WS, the display device DD, and a housing HS. The display device DD may include the display panel DP including the circuit layer CL with the transistors and the light-emitting devices ED1, ED2 and ED3 which are connected to the circuit layer CL, as described above. The housing HS, the display device DD, and the window structure WS may be sequentially stacked in the third direction.

The window structure WS may provide, e.g., an external display surface or a viewing surface (e.g., a display surface of a smartphone) recognized from outside of the electronic device ELD such as by a user of the device, and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may provide a planar area from which an image of the display device DD is substantially displayed, and to which an external input such as a user's touch/command is input to the device. The peripheral area PA may substantially correspond to a bezel area of the electronic device ELD. The peripheral area PA may provide a planar area from which an image is not displayed, without being limited thereto.

The display device DD and/or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In some embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, a sensor structure for touch sensing or fingerprint sensing may be disposed within the display panel DP or between the window structure WS and the display panel DP.

The housing HS may be provided as a frame structure or a rear housing of the display device DD or the electronic device ED. A cover panel (not shown) may be disposed between the housing HS and the display panel DP. The housing HS or the cover panel may include a plate (e.g., an SUS plate) which supports the display panel DP, a printed circuit board 400 (see FIG. 15), or the like. The housing HS or the cover panel may include an elastic body for absorbing shock of the display device DD.

Referring to FIG. 15, a pixel provided in plural including a plurality of pixels PX11 to PXnm may be arranged in the display area DA of the display panel DP.

According to embodiments, a pixel circuit including scan lines (or gate lines) SL1 to SLn forming first to n^{th} rows and data lines DL1 to DLm forming first to m^{th} columns may be arranged on the base substrate BS of the display device DD or the display panel DP. Each of the pixels PX11 to PXnm may be connected to a scan line of a corresponding row among a plurality of the scan lines SL1 to SLn and a data line of a corresponding column among a plurality of the data lines DL1 to DLm.

For example, the scan lines SL1 to SLn may be connected to the circuit layer CL at the gate electrode 230 included in the transistors TR1, TR2 and TR3 (see FIG. 1). The data lines DL1 to DLm may be connected to the circuit layer CL, e.g., at the connection electrode 250 serving as a source electrode.

Each of the pixels PX11 to PXnm may include the above-described pixel circuit and the light-emitting device. Although not illustrated in detail in FIG. 15, the pixel circuit may further include wirings such as a power line, a ground line, or the like.

FIG. 15 illustrates that the data lines DL1 to DLm extend in the second direction and the scan lines SL1 to SLn extend in the first direction, but the invention is not limited to the construction of FIG. 15.

A peripheral circuit PC may be disposed in the peripheral area PA of the electronic device ELD or the non-display area NDA of the display device DD. For example, the peripheral circuit PC may include a gate driving circuit. The gate driving circuit may be integrated into the display panel DP through an oxide semiconductor gate (OSG) driver circuit process, an amorphous silicon gate (ASG) driver circuit process, or a polysilicon gate driver (PSG) circuit process.

The electronic device ELD may further include a printed circuit board 400. A pad provided in plural including pads 195 of the pixel circuit (e.g., defined by a portion of the data lines) may be arranged at one side of the non-display area NDA. The printed circuit board 400 may be electrically connected to the pixel circuit at the pads 195. For example, the printed circuit board 400 may be electrically connected to the pads 195 by a heating-compression process using a conductive intermediation structure such as an anisotropic conductive film (ACF).

The pads 195 and a driving circuit element IC may be electrically connected to each other, through the printed circuit board 400. The driving circuit element IC may include an integrated circuit chip. In some embodiments, the integrated circuit chip may be mounted on the printed circuit board 400 in a chip-on-film (COF) form.

The driving circuit element IC may include a driving circuit of the display device DD and a driving circuit (e.g., an application processor (AP) chip) of the electronic device ELD. The driving circuit element IC may further include a circuit board such as a main board on which a chip including the driving circuit is mounted.

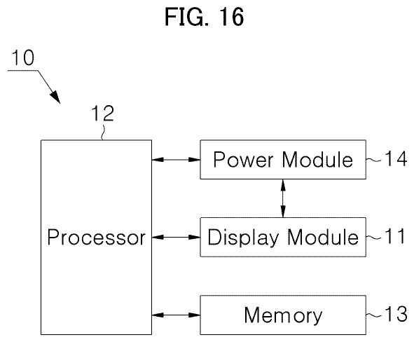

FIG. 16 is a block diagram of an electronic device 10 according to an embodiment.

Referring to FIG. 16, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module which converts a power supplied by the power supply module to a generate power required for the operation of the electronic device 10.

At least one of components of the electronic device 10 as described above may be included in the display device DD according to the above-described embodiments. Additionally, some of individual modules functionally included in one module may be included in the display device DD, and others may be provided separately from the display device DD. For example, the display module 11 may include the display device DD, and the processor 12, the memory 13 and the power module 14 may be provided in the form of another device in the electronic device 10 different from the display device DD.

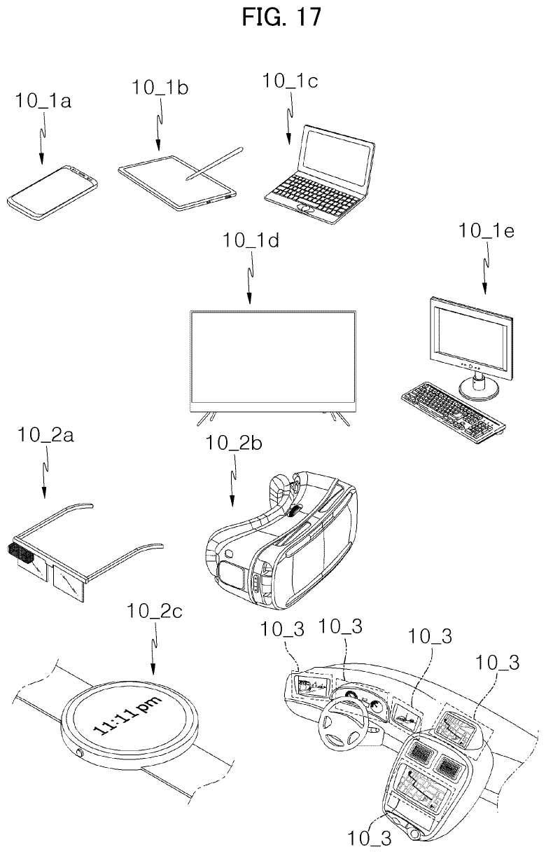

FIG. 17 is a schematic diagram of electronic devices according to various embodiments.

Referring to FIG. 17, non-limiting examples of various electronic devices to which the display device DD according to the above-described embodiments is applied include an electronic device (ELD or 10) for displaying an image such as a smartphone 10_1a, a tablet PC 10_1b, a laptop 10_1c, a television (TV) 10_1d, a desk monitor 10_1e, or the like, a wearable electronic device including a display module 11 such as smart glasses 10_2a, a head mounted display 10_2b, a smart watch 10_2c, or the like, a vehicle electronic device 10_3 including a display module DM such as a center information display (CID) disposed at a vehicle instrument panel, a center fascia, a dashboard, etc., a head-up display, a room mirror display, or the like. The electronic device may include a virtual reality glass or an augmented reality glass.

What is claimed is:

1. A display device, comprising:
a circuit layer; and
light-emitting devices electrically connected to the circuit layer, each of the light-emitting devices including a pixel electrode, an optical compensation layer, a light-emitting portion and a counter electrode;
the pixel electrodes of the light-emitting devices including a first pixel electrode, a second pixel electrode and a third pixel electrode; and
the optical compensation layers of the light-emitting devices covering each of the first pixel electrode and the second pixel electrode among the first pixel electrode, the second pixel electrode and the third pixel electrode,
wherein a thickness of the optical compensation layer covering the first pixel electrode is greater than a thickness of the optical compensation layer covering the second pixel electrode.

2. The display device of claim 1, wherein
each of the first pixel electrode, the second pixel electrode and the third pixel electrode of the pixel electrodes includes a transparent conductive oxide pattern, and
the optical compensation layer includes a transparent conductive oxide material different from a material of the transparent conductive oxide pattern.

3. The display device of claim 2, wherein
the first pixel electrode, the second pixel electrode and the third pixel electrode each includes indium tin oxide, and
the optical compensation layer includes indium zinc oxide.

4. The display device of claim 2, wherein each of the first pixel electrode, the second pixel electrode and the third pixel electrode comprises a first transparent conductive oxide pattern, a metal pattern and a second transparent conductive oxide pattern sequentially stacked from the circuit layer.

5. The display device of claim 2, wherein the optical compensation layer comprising:
a first optical compensation layer covering the first pixel electrode, and
a second optical compensation layer covering the second pixel electrode; and
the thickness of each of the first optical compensation layer and the second optical compensation layer is greater than a thickness of the transparent conductive oxide pattern included in the first pixel electrode and the second pixel electrode.

6. The display device of claim 1, wherein the optical compensation layer comprising:
a first optical compensation layer which covers a top surface and a side surface of the first pixel electrode, and
a second optical compensation layer which covers a top surface and a side surface of the second pixel electrode and is separated from the first optical compensation layer.

7. The display device of claim 6, wherein the first optical compensation layer and the second optical compensation layer includes a tip portion extending along the circuit layer in a direction toward the second optical compensation layer and the first optical compensation layer, respectively.

8. The display device of claim 6, wherein the light-emitting portion is in contact with the first optical compensation layer and the second optical compensation layer, and is in contact with the third pixel electrode.

9. The display device of claim 8, wherein the light-emitting devices include:
a first light-emitting device including the first pixel electrode and the first optical compensation layer,
a second light-emitting device including the second pixel electrode and the second optical compensation layer, and
a third light-emitting device including the third pixel electrode,
wherein the first light-emitting device emits red light, the second light-emitting device emits blue light, and the third light-emitting device emits green light.

10. The display device of claim 1, wherein
the light-emitting portion comprising a first emission layer on the first pixel electrode, a second emission layer on the second pixel electrode, and a third emission layer on the third pixel electrode, and
the first emission layer, the second emission layer and the third emission layer are emission layers of different colors.

11. The display device of claim 10, wherein the first emission layer is a red emission layer, the second emission layer is a blue emission layer, and the third emission layer is a green emission layer.

12. A method of providing a display device, comprising:
providing a circuit layer;
providing a first pixel electrode, a second pixel electrode and a third pixel electrode of light-emitting devices electrically connected to the circuit layer;
providing an optical compensation layer covering the first pixel electrode, the second pixel electrode and the third pixel electrode;
providing on the optical compensation layer, a first photoresist pattern which overlaps the first pixel electrode and a second photoresist pattern which overlaps the second pixel electrode, a thickness of the second photoresist pattern being smaller than a thickness of the first photoresist pattern;
removing portions of the optical compensation layer by an etching process using the first photoresist pattern and the second photoresist pattern as etching masks, to:
form a first optical compensation pattern covering the first pixel electrode, and
form a second optical compensation pattern covering the second pixel electrode;
reducing the thickness of the second photoresist pattern to expose a top surface of the second optical compensation pattern from the second photoresist pattern;
reducing a thickness of the second optical compensation pattern, by etching from the top surface, to form a remaining second optical compensation pattern;
removing the first photoresist pattern after the etching of the second optical compensation layer from the top surface;
providing a light-emitting portion of the light-emitting devices on the first optical compensation pattern, the remaining second optical compensation pattern, and the third pixel electrode; and
providing a counter electrode of the light-emitting devices on the light-emitting portion.

13. The method of claim 12, wherein the providing of the first photoresist pattern and the second photoresist pattern comprises:
providing a photoresist layer covering the optical compensation layer; and
patterning the photoresist layer to:
remove an entire thickness portion of the photoresist layer which is on the third pixel electrode, and
remove a partial thickness portion of the photoresist layer which is on the second pixel electrode.

14. The method of claim 13, wherein the patterning of the photoresist layer comprises an exposure process using a mask having a full-tone portion aligned over the third pixel electrode and a half-tone portion aligned over the second pixel electrode.

15. The method of claim 12, wherein the reducing of the thickness of the second photoresist pattern comprises providing a second photoresist residual pattern on a side surface of the second optical compensation pattern.

16. The method of claim 12, wherein the reducing of the thickness of the second photoresist pattern comprises reducing a thickness of the first photoresist pattern so that a top surface of the first optical compensation pattern is not exposed.

17. The method of claim 12, wherein
each of the first pixel electrode, the second pixel electrode and the third pixel electrode includes indium tin oxide, and
the optical compensation layer includes indium zinc oxide.

18. The method of claim 17, wherein the etching process which removes the portions of the optical compensation layer comprises using an etchant solution having a higher etching selectivity for the optical compensation layer than each of the first pixel electrode, the second pixel electrode, the third pixel electrode.

19. An electronic device comprising:
a display device;
a memory; and
a processor executing data included in the memory to control an operation of the display device, wherein the display device comprises:
a circuit layer; and
light-emitting devices electrically connected to the circuit layer, each of the light-emitting devices including a pixel electrode, an optical compensation layer, a light-emitting portion and a counter electrode;
the pixel electrodes of the light-emitting devices including a first pixel electrode, a second pixel electrode and a third pixel electrode; and
the optical compensation layers of the light-emitting devices covering each of the first pixel electrode and the second pixel electrode among the first pixel electrode, the second pixel electrode and the third pixel electrode,
wherein a thickness of the optical compensation layer covering the first pixel electrode is greater than a thickness of the optical compensation layer covering the second pixel electrode.

20. The electronic device of claim 19, wherein the electronic device includes virtual reality or augmented reality glasses, a smartphone, a tablet personal computer, a laptop, a television, a desk monitor, smart glasses, a head-mounted display, a smart watch, or a vehicle display.
